(19) United States
(12) Patent Application Publication
(10) Pub. No.: US 2010/0101387 A1
(43) Pub. Date: Apr. 29, 2010

(54) CRYSTAL GROWING SYSTEM AND METHOD THEREOF

(76) Inventors: Kedar Prasad Gupta, Hollis, NH (US); Carl Richard Schwerdtfeger, JR., Amherst, NH (US); Govindhan Dhanaraj, Merrimack, NH (US)

Correspondence Address: GLOBAL IP SERVICES, PLLC, 10 CRESTWOOD LANE, NASHUA, NH, 03062, US

(21) Appl. No.: 12/588,656

(22) Filed: Oct. 22, 2009

Related U.S. Application Data
(60) Provisional application No. 61/108,213, filed on Oct. 24, 2008.

(51) Int. Cl. B26D 9/00; C30B 15/20

(52) U.S. Cl. 83/39; 117/217; 117/216; 117/3

(57) ABSTRACT

A controlled heat extraction system and method thereof is disclosed. In one embodiment, a system includes a housing to form a chamber. The system further includes a seed cooling component adapted to support a bottom of the crucible and to receive a coolant fluid to cool the supported portion of the crucible. The system also includes at least one heating element substantially surrounding the seed cooling component and the crucible to heat the crucible, where the seed cooling component along with the crucible is movable relative to the at least one heating element. Furthermore, the system includes an insulating element substantially surrounding the crucible, the seed cooling component and the at least one heating element. Additionally, the system includes a gradient control device (GCD) movable relative to the insulating element, the at least one heating element, the seed cooling component and the crucible over a range of positions.

### RELATED APPLICATION

This application claims priority under 35 U.S.C. 119 to U.S. Provisional Application No. 61/108,213, entitled “SYSTEM AND METHOD FOR GROWING CRYSTALS” by Advanced RenewableEnergy Co., filed on Oct. 24, 2008, which is incorporated herein its entirety by reference.

### FIELD OF TECHNOLOGY

The present invention relates to a field of growing crystals and more particularly relates to a crystal growing system and method.

### BACKGROUND

Advancement in solid state lighting utilizing high brightness white, blue and green light emitting diodes (LEDs) over the past decade represents a drastic development in the lighting industry, providing significant performance, environmental and economic improvements compared to traditionally used incandescent or fluorescent lighting. Incandescent lamps are inefficient, dissipate about 90% of consumed power as heat and last only about 2,000 hours. Fluorescent lamps contain toxic mercury vapor, which creates an environmental and disposal problem. Whereas, LEDs do not contain mercury and are about 6 times more efficient than traditional incandescent lamps in terms of energy consumption, while providing up to 60,000 hours of light.

These advantages, along with their durability, small form factor, excellent color performance, and continuously decreasing costs, have led to a rapidly growing demand for the LEDs in applications, such as small displays for mobile devices, flashes for digital cameras, backlighting units for displays used in computer monitors, liquid crystal display (LCD) televisions, public display signs, automotive lights, traffic signals, and general and specialty lighting for domestic and commercial premises.

Typically, LEDs are fabricated by growing several types of gallium nitride (GaN) crystalline active layers on a compatible substrate (also referred to as “wafer”). Further, the LEDs thus fabricated may have a mismatch between a crystal lattice of the compatible substrate and the GaN crystalline active layers. The mismatch must be as small as possible, so that a single crystal layer can be grown on a substrate. The substrate must also have a high transparency, stability at temperatures up to 1100° C. or more, comparable thermal expansion and heat conduction with the grown GaN crystalline active layers. The physical properties of the substrates (also referred to as “wafers”) are close to those of GaN and other layers, such as aluminum nitride (AlN), GaN, indium gallium nitride (InGaN) and indium gallium aluminum (InGaAl).

Even though there are several other potential substrate materials available such as silicon carbide (SiC), silicon (Si), zinc oxide (ZnO) and GaN, sapphire (Al₂O₃) appears to be the most popular substrate material for LEDs and other GaN device applications. Currently, 2 to 4 inches diameter sapphire wafers of thickness of 150-600 micrometer (μm) are used for the fabrication of LEDs. In sapphire, (0001) plane orientation has smallest mismatch with GaN when compared with other crystallographic orientations.

Currently, sapphire crystals are grown commercially by using one of the following techniques:

1) Czochralski method (Cz);

2) Kyropolous method (Ky);

3) Edge-defined Film Growth (EFG);

4) Bridgeman (Br) method and variants of Br;

5) Heat Exchanger Method (HEM); and

6) Gradient Freeze (GF) and variants of GF.

However, the above methods have one or more shortcomings, such as: 1) presence of bubbles in the crystal, 2) defects and lattice distortion, 3) crucible design issues, 4) difficulty in measuring actual crystal growth rate and 5) not cost effective due to an a-axis growth process. These shortcomings typically make yield low and cost of the wafer high.

### SUMMARY

A crystal growing system and method thereof is disclosed. According to one aspect of the present invention, a system for growing crystals from a molten charge material in a crucible includes a housing to form a chamber. The system further includes a seed cooling component, adapted to support a bottom of the crucible and to receive a coolant fluid to cool the supported portion of the crucible. The system also includes at least one heating element substantially surrounding the seed cooling component and the crucible to heat the crucible, where the seed cooling component along with the crucible is movable relative to the at least one heating element. Furthermore, the system includes an insulating element substantially surrounding the crucible, the seed cooling component and the at least one heating element.

Additionally, the system may include a gradient control device (GCD) movable relative to the insulating element, the at least one heating element, the seed cooling component and the crucible over a range of positions. The seed cooling component along with the crucible, the at least one heating element, the insulating element and the GCD are enclosed in the housing.

The system may include a temperature control and a power control system to precisely control the temperature of the at least one heating element. Further, the system may include a motion controller to independently control the movement of the seed cooling component along with the crucible and the position of the GCD. Moreover, the system may include a vacuum pump to create and maintain a vacuum inside the housing during the crystal growth.

According to another aspect of the present invention, a method for growing a crystal includes heating a charge material along with a seed crystal in a crucible to substantially slightly above a melting temperature of the charge material and maintaining the melt of the charge material for a pre-determined amount of time for homogenization. The method also includes substantially simultaneously cooling a bottom of the crucible to keep the seed crystal intact. Further, the method includes continually growing the crystal by substantially lowering the temperature of the melt and substantially lowering the crucible to maintain growth rate of the continually growing crystal to produce a substantially larger crystal.

The method may include placing the seed crystal at the bottom of the crucible and placing the charge material in the crucible such that the seed crystal is substantially fully covered by the charge material. The method may also include extracting the larger crystal from the crucible upon completion of the crystal growth, coring the extracted larger crystal to produce a substantially cylindrical ingot, and slicing the cored cylindrical ingot to produce wafers.

According to yet another aspect of the present invention, a method for growing a crystal in a controlled heat extraction system (CHES), having a housing, a seed cooling component adapted to support a bottom of a crucible and to receive a coolant fluid to cool the supported portion of the crucible, at least one heating element, an insulating element and a GCD, includes heating a charge material along with a seed crystal in a crucible to substantially slightly above a melting temperature of the charge material using the at least one heating element. Further, the method includes maintaining the melt of the charge material for a pre-determined amount of time for homogenization using the at least one heating element. The method also includes substantially simultaneously cooling a bottom of the crucible to keep the seed crystal intact by flowing the coolant fluid through the seed cooling component.

Further, the method includes continually growing the crystal to produce a substantially larger crystal. For continually growing the crystal, the cooling rate at the bottom of the crucible is progressively increased by flowing the coolant fluid through the seed cooling component. The crucible is also substantially lowered with respect to the at least one heating element using the seed cooling shaft to maintain growth rate of the continually growing crystal to produce a larger crystal.

According to a further another aspect of the present invention, a system for growing crystals from a molten charge material in a crucible includes a housing to form a chamber. The system also includes a seed cooling component adapted to support a bottom of the crucible and to receive a coolant fluid to cool the supported portion of the crucible. The system further includes at least one heating element substantially surrounding the seed cooling component and the crucible. The at least one heating element is adapted to heat the crucible. The at least one heating element is also adapted to substantially slowly lower temperature inside the chamber during the crystal growth. The at least one heating element is designed to cool the chamber at a rate approximately in the range of about 0.02 to 5° C./hr.

Additionally, the system includes an insulating element substantially surrounding the crucible, the seed cooling component and the at least one heating element. Moreover, the system includes a GCD movable relative to the insulating element, the at least one heating element, the seed cooling component and the crucible over a range of positions, and where the seed cooling component along with the crucible, the at least one heating element, the insulating element and the GCD are enclosed in the housing.

According to yet a further another aspect of the present invention, a system for growing crystals from a molten charge material in a crucible includes a housing to form a chamber. The system also includes a seed cooling component adapted to support a bottom of the crucible and to receive a coolant fluid to cool the supported portion of the crucible. The system further includes at least one heating element substantially surrounding the seed cooling component and the crucible.

The at least one heating element is adapted to heat the crucible. The at least one heating element is also adapted to substantially slowly lower temperature inside the chamber during the crystal growth. The at least one heating element is designed to cool the chamber at a rate approximately in the range of about 0.02 to 5° C./hr. The seed cooling component along with the crucible is movable relative to the at least one heating element.

Additionally, the system includes an insulating element substantially surrounding the crucible, the seed cooling component and the at least one heating element. The system also includes a GCD movable relative to the insulating element, the at least one heating element, the seed cooling component and the crucible over a range of positions, and where the seed cooling component along with the crucible, the at least one heating element, the insulating element and the GCD are enclosed in the housing.

The methods and systems disclosed herein may be implemented in any means for achieving various aspects. Other features will be apparent from the accompanying drawings and from the detailed description that follow.

### BRIEF DESCRIPTION OF THE DRAWINGS

Various preferred embodiments are described herein with reference to the drawings, wherein:

FIG. 1A is a cross-sectional view of a furnace used in growing a single crystal about the c-axis, according to one embodiment;

FIG. 1B is a cross-sectional view of a furnace used in growing a single crystal about the c-axis, according to another embodiment;

FIG. 1C is a cross-sectional view of a furnace used in growing a single crystal about the c-axis, according to yet another embodiment;

FIGS. 2 through 4 illustrate a process of formation of a cored c-axis cylindrical ingot from a seed crystal, according to one embodiment;

FIG. 5 is a process flowchart of an exemplary method of growing a single crystal about the c-axis using the furnace, such as those shown in FIG. 1A, and thereafter producing wafers using the single crystal, according to one embodiment; and

FIG. 6 is a schematic diagram illustrating a controlled heat extraction system (CHES) with the furnace, such as those shown in FIG. 1A, used in growing the single crystal along the c-axis, according to one embodiment.

The drawings described herein are for illustration purposes only and are not intended to limit the scope of the present disclosure in any way.

### DETAILED DESCRIPTION

A crystal growing system and method thereof is disclosed. In the following detailed description of the embodiments of the invention, reference is made to the accompanying drawings that form a part hereof, and in which are shown, by way of illustration, specific embodiments in which the invention may be practiced. These embodiments are described in sufficient detail to enable those skilled in the art to practice the invention, and it is to be understood that other embodiments may be utilized and that changes may be made without departing from the scope of the present invention. The following detailed description is, therefore, not to be taken in a limiting sense, and the scope of the present invention is defined by the appended claims.

The terms ‘larger solidified single crystal’, ‘larger single crystal’, ‘larger crystal’ and ‘single crystal’ are used interchangeably throughout the document. Also, the terms ‘convex crystal growing surface’ and ‘crystal growing surface’ are used interchangeably throughout the document. Further, the term ‘about an axis’ refers to growing a single crystal approximately −15° to +15° from the axis, where the axis may be one of c-axis, a-axis, m-axis or r-axis.

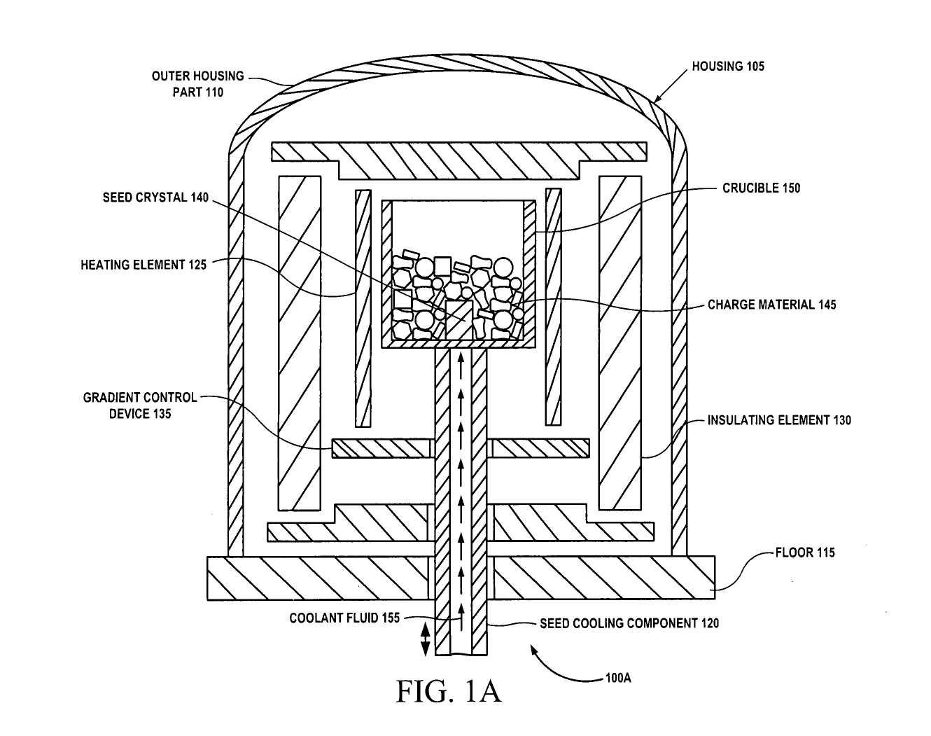

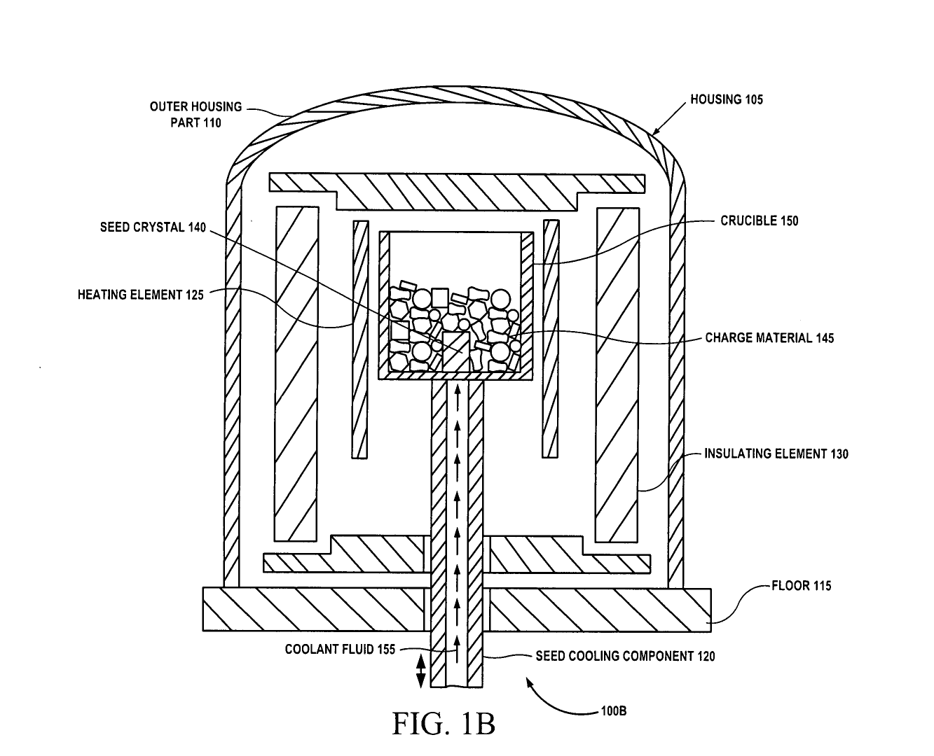

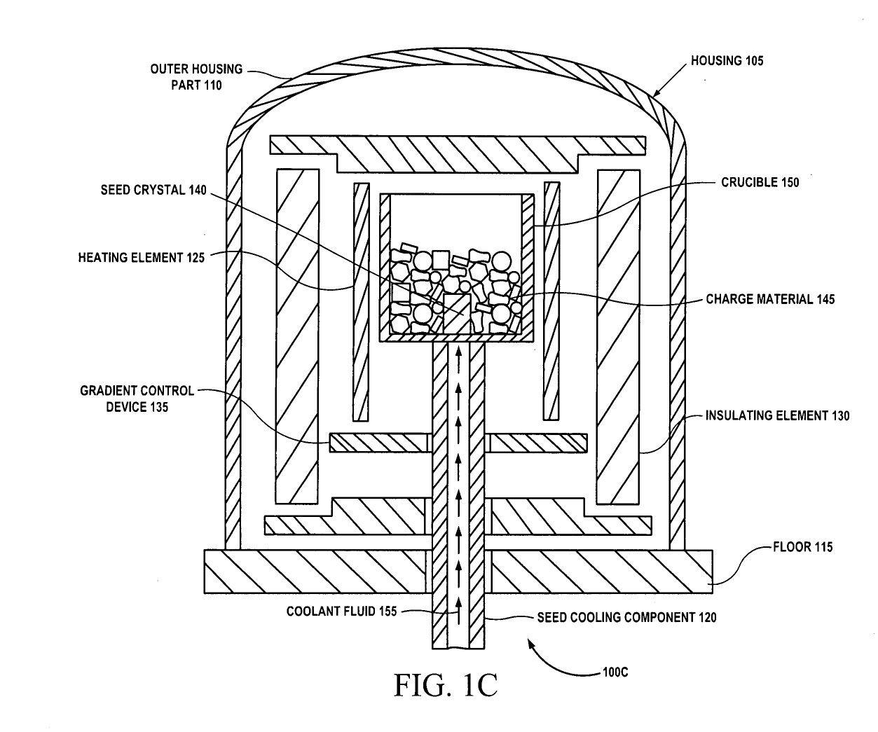

FIG. 1A is a cross-sectional view of a furnace 100A used in growing a single crystal about the c-axis, according to one embodiment. In FIG. 1A, the furnace 100A includes a housing 105. The housing 105 includes an outer housing part 110 and a floor 115. The outer housing part 110 and the floor 115 together form a chamber. The furnace 100A also includes a seed cooling component 120, a heating element(s) 125, an insulating element 130, a gradient control device (GCD) 135 and a crucible 150, all of which are enclosed in the outer housing part 110.

The crucible 150 may be a container holding a seed crystal 140 (e.g., D shaped, circular shaped, etc.) and a charge material 145 (e.g., sapphire (Al₂O₃), silicon (Si), calcium fluoride (CaF2), sodium iodide (NaI), and other halide group salt crystals). As illustrated, the crucible 150 sits on the seed cooling component 120. The seed cooling component 120 may be a hollow component (e.g., made of a refractory metal such as tungsten (W), molybdenum (Mo), niobium (Nb), lanthanum (La), tantalum (Ta), rhenium (Re) or their alloys) that supports a bottom of the crucible 150. The seed cooling component 120 also receives a coolant fluid 155 (e.g., helium (He), neon (Ne) and hydrogen (H)) to cool the supported portion of the crucible 150 through the hollow portion.

The heating element(s) 125 substantially surrounds the seed cooling component 120 and the crucible 150. In one embodiment, the heating element(s) 125 is adapted to heat the crucible 150. In another embodiment, the heating element(s) 125 is adapted to substantially slowly lower temperature inside the chamber during crystal growth. For example, the heating element(s) 125 is designed to cool the chamber at a rate approximately in the range of about 0.02 to 5° C./hr.

In some embodiments, the seed cooling component 120 along with the crucible 150 is movable relative to the heating element(s) 125. In these embodiments, the seed cooling component 120 is moved through one or more openings in the floor 115 of the housing 105. The insulating element 130 substantially surrounds the seed cooling component 120, the heating element(s) 125 and the crucible 150 and prevents heat transfer from the furnace 100A. For example, the insulating element 130 may be made of material such as W, Mo, graphite (C), and high temperature ceramic materials. The GCD 135 is movable relative to the seed cooling component 120, the heating element(s) 125, the insulating element 130 and the crucible 150 over a range of positions.

In operation, the charge material 145 along with the seed crystal 140 in the crucible 150 is heated to substantially slightly above a melting temperature of the charge material 145 using the heating element(s) 125. For example, the charge material 145 is heated to a temperature approximately in the range of about 2040° C. to 2100° C. Once the charge material 145 is completely molten, the molten charge material (also referred to as melt of the charge material) is maintained for a pre-determined amount of time (e.g., 1 to 24 hours) for homogenization.

Simultaneously to the heating of the charge material 145, the bottom of the crucible 150 is cooled by flowing the coolant fluid 155 (e.g., at a rate of 10 to 100 liters per minute (lpm)) through the seed cooling component 120. The bottom of the crucible 150 is cooled such that the seed crystal 140 remains intact and not melted completely. After soaking the melt for homogenization, the growth of the crystal is initiated along the c-axis.

In one or more embodiments, as the crystal grows, the cooling rate at the bottom of the crucible 150 is increased progressively by ramping up the flow rate of the coolant fluid 155 (e.g., up to 600 lpm over a period of 24 to 96 hours) through the seed cooling component 120. Concurrently, the temperature of the melt is substantially lowered at a rate of 0.02 to 5° C./hr by substantially slowly lowering the temperature of the heating element(s) 125. As a result, the melt is under-cooled as well as a temperature gradient is generated between the growing crystal and the melt. The process of under-cooling the melt and generation of the temperature gradient between the growing crystal and the melt by substantially slowly lowering the temperature of the heating element(s) 125 is known as gradient freeze (GF).

Further, as the crystal grows taller, the effect of the coolant fluid 155 reduces and hence the growth rate of the crystal slows down steadily. To compensate for the reduced growth rate of the crystal, the crucible 150 is lowered substantially at a rate of 0.1 to 5 mm/hr by moving the seed cooling component 120. Also, the temperature gradient is substantially varied to ensure a continued growth of the crystal and to produce a larger solidified single crystal. The temperature gradient is varied by moving the GCD 135 at a rate of 0.1 to 5 mm/hr. In these embodiments, the larger solidified single crystal (e.g., weighing from 0.3 to 450 Kilograms) is grown in the furnace 100A about a high yield c-axis.

On completion of the crystal growth, temperature of the furnace 100A is reduced below the melting temperature of the charge material 145 to cool the larger solidified single crystal to a room temperature. This is achieved by lowering the temperature of the heating element(s) 125, reducing the flow of the coolant fluid 155 to stop removal of heat from the bottom of the crucible 150, and moving the GCD 135 to a favorable position to reduce the temperature gradient. Further, inert gas pressure inside the furnace 100A is increased before the larger solidified single crystal is extracted from the furnace 100A. One can envision that, larger single crystals can also be grown about a-axis, r-axis or m-axis using the above described furnace 100A.

FIG. 1B is a cross-sectional view of a furnace 100B used in growing a single crystal about the c-axis, according to another embodiment. The furnace 100B of FIG. 1B is similar to the furnace 100A of FIG. 1A, except the furnace 100B does not include a GCD and also the heating element(s) 125 is not designed to substantially lower the temperature of the chamber.

FIG. 1C is a cross-sectional view of a furnace 100C used in growing a single crystal about the c-axis, according to another embodiment. The furnace 100C of FIG. 1C is similar to the furnace 100A of FIG. 1A, except in the furnace 100C, the seed cooling component 120 is fixed such that the seed cooling component along with the crucible 150 is immovable with respect to the heating element(s) 125.

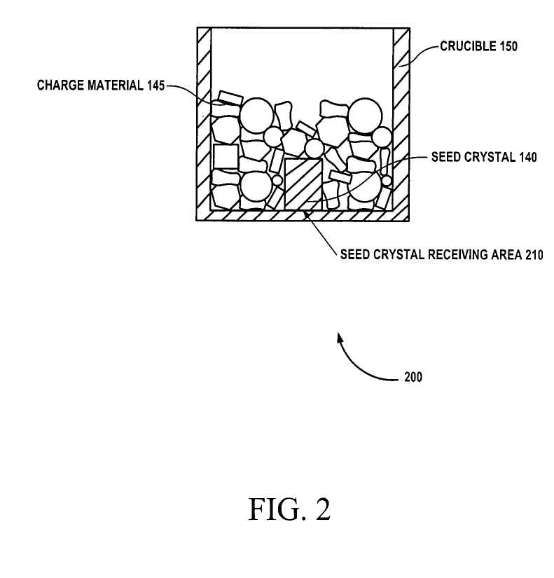

FIGS. 2 through 4 illustrate a process of formation of a cored c-axis cylindrical ingot 440 from the seed crystal 140, according to one embodiment. In one example embodiment, the cored c-axis cylindrical ingot 440 may be a sapphire ingot. In particular, FIG. 2 shows the crucible 150 having the seed crystal 140 along with the charge material 145. The crucible 150 may be made of a metallic material (e.g., Mo, W, or alloys of Mo and W) or a non-metallic material (e.g., graphite (C), boron nitride (BN), and the like). Further, the crucible 150 is capable of holding 0.3 to 450 Kilograms of the charge material 145.

The crucible 150 includes a seed crystal receiving area 210. The seed crystal receiving area 210 holds the seed crystal 140 in the crucible 150. In one embodiment, the seed crystal receiving area 210 allows a seed crystal of predetermined shape or size to be oriented in only one way or in any way in the seed crystal receiving area 210. The phrase ‘oriented in only one way’ refers to positioning of a D shaped seed crystal in only one position in the seed crystal receiving area 210, whereas the phrase ‘oriented in any way’ refers to positioning of a circular shaped seed crystal in any position within 360° in the seed crystal receiving area 210. It can be noted that the orientation of the seed crystal 140 in the seed crystal receiving area 210 may control orientation of the growing crystal about the c-axis. As illustrated in FIG. 2, the charge material 145 is placed in the crucible 150 in such a way that the seed crystal 140 is substantially fully covered by the charge material 145.

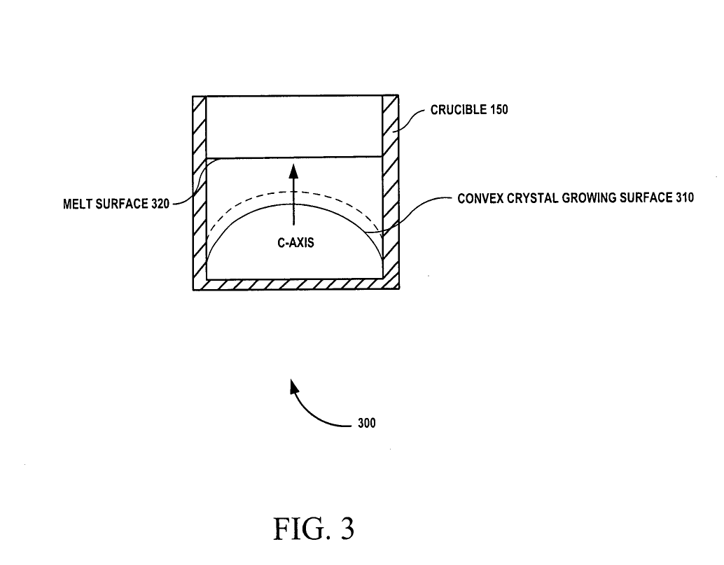

In an exemplary process, the crucible 150 with the charge material 145 and the seed crystal 140 is placed in the furnace (e.g., the furnace 100A, the furnace 100B or furnace 100C) for growing a larger single crystal about the c-axis. The charge material 145 then is heated above the melting temperature of the charge material 145. Further, the melt is maintained for the pre-determined amount of time for homogenization, to initiate the crystal growth about the c-axis. Concurrently, the bottom of the crucible 150 is cooled by flowing helium through the seed cooling component 120 to keep the seed crystal 140 intact. Accordingly, the seed crystal 140 starts growing about the c-axis along a crystal growing surface, as illustrated in FIG. 3.

In one embodiment, the crystal growing surface is formed starting from melting a small portion of a top surface (e.g., c-face) of the seed crystal 140. The small portion of the top surface of the seed crystal 140 is melted by increasing the temperature of the melt and/or reducing the flow rate of helium (e.g., from 90 lpm to 80 lpm) through the seed cooling component 120, resulting in a convex (or dome) shaped crystal growing surface 310. The convex crystal growing surface 310 includes micro steps made of a-plane and c plane and is maintained during the crystal growth. The convex crystal growing surface 310 assists substantially to increase the growth rate of the crystal about the c-axis.

For continually growing the crystal along the convex crystal growing surface 310, the cooling rate at the bottom of the crucible 150 is increased and the temperature of the melt is lowered. Further, the crucible 150 is lowered with respect to the heating element(s) 125 to compensate for the sluggish growth rate of the crystal (as the effect of the coolant fluid 155 is reduced). Also, the GCD 135 is moved such that the temperature gradient is varied. The above-mentioned process enables the crystal to grow continually along the c-axis resulting in a larger single crystal. As illustrated in FIG. 3, the crystal grows inside the melt predominantly along the c-direction.

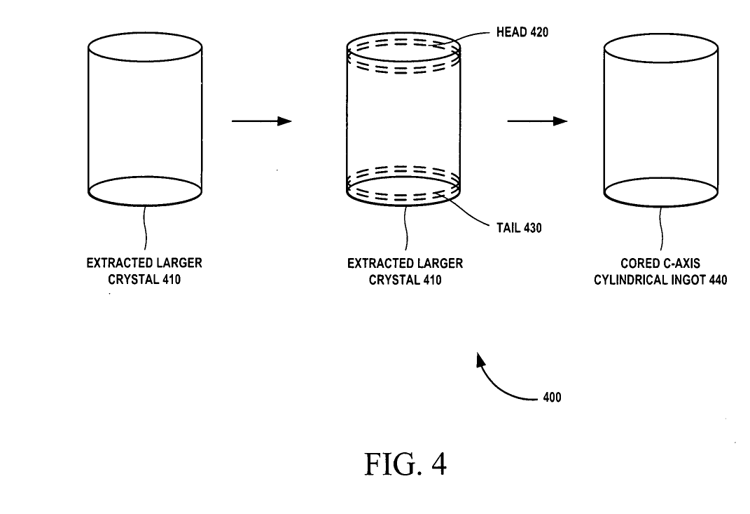

On completion of the crystal growth, the larger single crystal is extracted from the crucible 150. The extracted larger crystal 410 is then cored. As illustrated in FIG. 4, a top surface (e.g., a head 420 and a tail 430) of the extracted larger crystal 410 is cored. Thus, the cored c-axis cylindrical ingot 440 is obtained (e.g., with minimum grinding). Finally, the cored c-axis cylindrical ingot 440 is sliced to produce wafers that are used in optics and semiconductor applications.

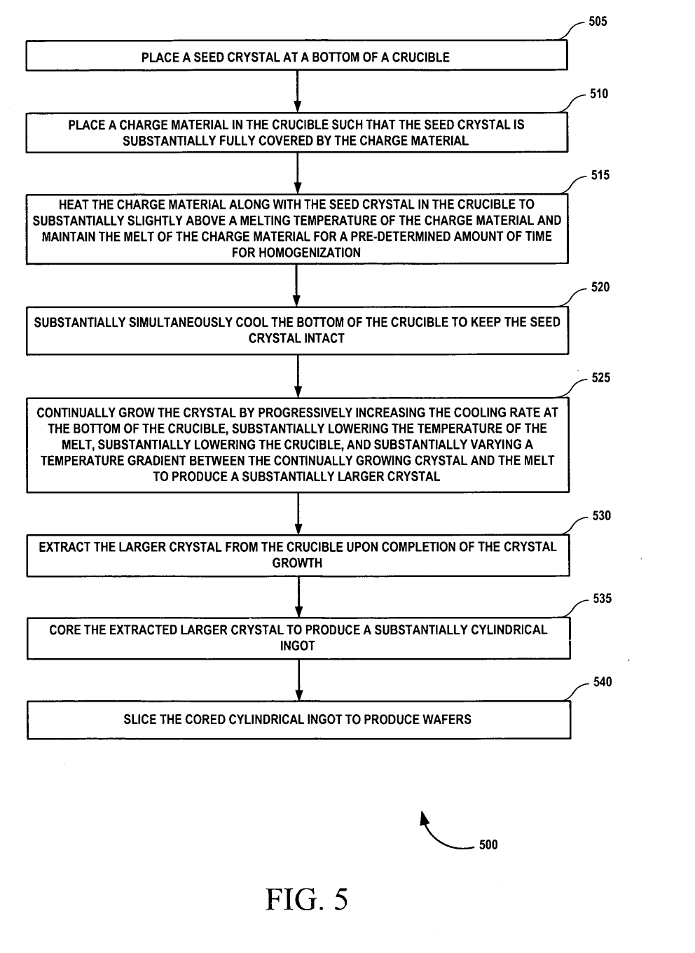

FIG. 5 is a process flowchart 500 of an exemplary method of growing a single crystal about the c-axis using the furnace 100A, such as those shown in FIG. 1A, and thereafter producing wafers using the single crystal, according to one embodiment. In step 505, a seed crystal (e.g., sapphire seed crystal) is placed at a bottom of the crucible 150. In step 510, a charge material (e.g., a sapphire charge material) is placed in the crucible 150 such that the seed crystal is substantially fully covered by the charge material. Then, the crucible 150 with the charge material and the seed crystal is loaded into the furnace 100A.

In step 515, the charge material along with the seed crystal in the crucible 150 is heated (e.g., using the heating element(s) 125) to substantially slightly above the melting temperature (e.g., in the range of about 2040° C. to 2100° C.) of the charge material. Then, the melt of the charge material is maintained above the melting temperature for a pre-determined amount of time (e.g., 1 to 24 hours). In one example embodiment, the melt of the charge material is maintained above the melting temperature for homogenization.

Further, in step 520, the bottom of the crucible 150 is cooled (e.g., simultaneously to the heating process in step 515) to keep the seed crystal intact with minimal desired melting. In case of the seed crystal oriented along the c-axis, the minimal desired melting may include melting a portion of a top surface (e.g., c-face) of the seed crystal to form a convex crystal growing surface, as shown in FIG. 3. The convex crystal growing surface is a true non-habit face (e.g., not the true c-face) having multi-steps made of a-plane and c-plane. The convex crystal growing surface helps safely increase a growth rate of the crystal about the c-axis.

In one embodiment, the bottom of the crucible 150 is cooled using helium when the melt of the charge material is above the melting temperature. For example, the helium is flown through the seed cooling component 120 supporting the bottom of the crucible 150 at a rate approximately in the range of about 10 to 100 lpm. In step 525, a crystal is continually grown about the c-axis to produce a larger crystal.

During the crystal growth, the cooling rate at the bottom of the crucible 150 is increased substantially by increasing the flow rate of helium (e.g., up to 600 lpm over a period of 24 to 96 hours). Also, the temperature of the melt is lowered by substantially slowly lowering the temperature of the heating element(s) 125 at a rate of about 0.02 to 5° C./hr. As a result, a temperature gradient is generated between the continually growing crystal and the melt. Further, as the crystal grows taller, the crucible 150 is lowered with respect to the heating element(s) 125 using the seed cooling component 120 at a rate of about 0.1 to 5 mm/hr. The crucible 150 is lowered to maintain the growth rate of the continually growing crystal. Also, the temperature gradient is substantially varied by moving the GCD 135 to ensure continued growth of the crystal to produce the larger crystal.

In step 530, the larger crystal is extracted from the crucible 150 upon completion of the crystal growth. In step 535, the extracted larger crystal is cored to produce a substantially cylindrical ingot. In one embodiment, the cylindrical ingot is produced by coring substantially perpendicular to the top surface of the extracted larger crystal, as shown in FIG. 4. In step 540, the cored cylindrical ingot is sliced to produce wafers.

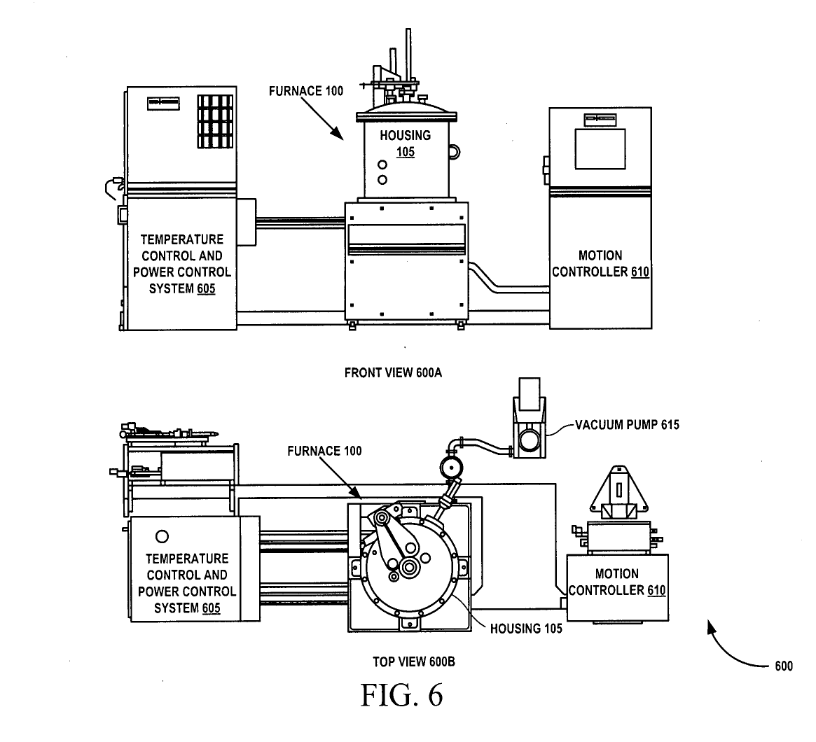

FIG. 6 is a schematic diagram illustrating a controlled heat extraction system (CHES) 600 with the furnace 100A, such as those shown in FIG. 1A, used in growing the single crystal along the c-axis, according to one embodiment. In particular, FIG. 6 illustrates a front view 600A and a top view 600B of the CHES 600 used in growing the single crystal. The front view 600A and the top view 600B together illustrate various components of the CHES 600.

As illustrated, the CHES 600 includes the furnace 100A with the housing 105, a temperature control and power control system 605, a motion controller 610 and a vacuum pump 615. As mentioned above, the furnace 100A for growing crystals includes the seed cooling component 120 along with the crucible 150, the heating element(s) 125, the insulating element 130 and the GCD 135 enclosed in the housing 105. The temperature control and power control system 605 is configured to precisely control the temperature of the heating element(s) 125 within an average at least ranging from −0.2° C. to +0.2° C. In one example embodiment, temperature control and power control system 605 controls the temperature of the heating element(s) 125 such that the charge material 145 is heated above the melting temperature of the charge material 145. In another example embodiment, the temperature control and power control system 605 controls the temperature of the heating element(s) 125 such that the temperature of the heating element(s) 125 is substantially lowered at a rate of 0.02 to 5° C./hr.

The motion controller 610 is configured to control the movement of the seed cooling component 120 along with the crucible 150. For example, the motion controller 610 lowers the seed cooling component 120 along with the crucible 150 to maintain the growth rate of the crystal. The motion controller 610 is also configured to control the position of the GCD 135. For example, the motion controller 610 moves the GCD 135 over a range of positions to maintain the growth rate of the crystal. It can be noted that, the motion controller 610 is configured to independently control the movement of the seed cooling component 120 and the position of the GCD 135.

The vacuum pump 615 creates and maintains a vacuum (e.g., partial vacuum or full vacuum) inside the housing 105 such that the crystal can be grown in vacuum. It can be noted that, the furnace 100A in the CHES 600 can also grow crystals under partial gas pressures. Although the above description of the CHES 600 is made with respect to the furnace 100A, one can envision that the CHES 600 may also use the furnace 1008 or the furnace 100C for growing the single crystals along the c-axis.

Although the foregoing description is made with reference to growing a single crystal along the c-axis, the methods and systems described herein can be implemented for growing single crystals along other axis such as a-axis, r-axis or m-axis. In various embodiments, the methods and systems described in FIGS. 1 through 6, enable growing of high yield c-axis crystals with low defects and bubbles using a combination of features. The combination of features range from 30-75% seed crystal cooling, 10-30% melt cooling, 10-30% crucible lowering, and 10-30% temperature gradient control. The above-described CHES system and the processes result in high yield during manufacturing of c-cut wafers because of the c-axis growth process. This helps in substantially reducing the wafer cost while retaining high structural perfection. The above-described CHES can also be used for growing several other types of crystals in optics and semi-conductor applications.

Although the present embodiments have been described with reference to specific example embodiments, it will be evident that various modifications and changes may be made to these embodiments without departing from the broader spirit and scope of the various embodiments. In addition, it will be appreciated that the various operations, processes, and methods disclosed herein may be may be performed in any order. Accordingly, the specification and drawings are to be regarded in an illustrative rather than a restrictive sense.

What is claimed is:

1. A system for growing crystals from a molten charge material in a crucible, comprising:
a housing to form a chamber;
a seed cooling component adapted to support a bottom of the crucible and to receive a coolant fluid to cool the supported portion of the crucible;
at least one heating element substantially surrounding the seed cooling component and the crucible to heat the crucible, wherein the seed cooling component along with the crucible is movable relative to the at least one heating element; and
an insulating element substantially surrounding the crucible, the seed cooling component and the at least one heating element.

2. The system of claim 1, further comprising:
a gradient control device (GCD) movable relative to the insulating element, the at least one heating element, the seed cooling component and the crucible over a range of positions, and wherein the seed cooling component along with the crucible, the at least one heating element, the insulating element and the GCD are enclosed in the housing.

3. The system of claim 2, wherein the at least one heating element is adapted to substantially slowly lower temperature inside the chamber during crystal growth and wherein the temperature of the at least one heating element is lowered at a rate approximately in the range of about 0.02 to 5° C./hr.

4. The system of claim 3, wherein the housing comprises an outer housing part for enclosing the seed cooling component along with the crucible, the at least one heating element, the insulating element and the GCD, and wherein the housing further comprises a floor having one or more openings through which the seed cooling component is moved.

5. The system of claim 1, wherein the crucible is capable of holding the molten charge material approximately in the range of about 0.3 to 450 Kilograms.

6. The system of claim 1, wherein the seed cooling component is made of a refractory metal selected from the group consisting of tungsten (W), molybdenum (Mo), niobium (Nb), lanthanum (La), tantalum (Ta), rhenium (Re) and their alloys.

7. The system of claim 1, further comprising a temperature control and power control system to precisely control the temperature of the at least one heating element.

8. The system of claim 7, further comprising a motion controller to independently control the movement of the seed cooling component along with the crucible and the position of the GCD.

9. The system of claim 8, further comprising a vacuum pump to create and maintain a vacuum inside the housing during the crystal growth.

10. The system of claim 1, wherein the at least one heating element is capable of heating the molten charge material in the crucible to a temperature approximately in the range of about 2040° C. to 2100° C.

11. The system of claim 1, wherein the molten charge material is selected from the group consisting of sapphire (Al₂O₃), silicon (Si), calcium fluoride (CaF₂), sodium iodide (NaI), and other halide group salt crystals.

12. The system of claim 1, wherein the crucible is made of a metallic material selected from the group consisting of Mo, W, and alloys of Mo and W.

13. The system of claim 1, wherein the crucible is made of a non-metallic material selected from the group consisting of graphite (C), and boron nitride (BN).

14. The system of claim 1, wherein the crucible includes a seed crystal receiving area which is configured for allowing a seed crystal of predetermined shape or size to be oriented in only one way or in any way in the seed crystal receiving area.

15. The system of claim 1, wherein the coolant fluid is a fluid selected from the group consisting of helium (He), neon (Ne), and hydrogen (H).

16. The system of claim 15, wherein the seed cooling component receives the coolant fluid at a rate approximately in the range of about 10 to 600 liters per minute (lpm).

17. The system of claim 16, wherein the GCD is moved relative to the insulating element, the at least one heating element, the seed cooling component and the crucible at a rate approximately in the range of about 0.1 to 5 mm/hr.

18. The system of claim 17, wherein the seed cooling component along with the crucible is moved at a rate approximately in the range of about 0.1 to 5 mm/hr.

19. A method for growing a crystal, comprising:
heating a charge material along with a seed crystal in a crucible to substantially slightly above a melting temperature of the charge material and maintaining the melt of the charge material for a pre-determined amount of time for homogenization;
substantially simultaneously cooling a bottom of the crucible to keep the seed crystal intact; and
continually growing the crystal by substantially lowering the temperature of the melt and substantially lowering the crucible to maintain growth rate of the continually growing crystal to produce a substantially larger crystal.

20. The method of claim 19, wherein the continually growing the crystal further comprises:
progressively increasing the cooling rate at the bottom of the crucible.

21. The method of claim 20, wherein the continually growing the crystal further comprises:
substantially varying a temperature gradient between the continually growing crystal and the melt.

22. The method of claim 21, further comprising:
placing the seed crystal at the bottom of the crucible; and
placing the charge material in the crucible such that the seed crystal is substantially fully covered by the charge material.

23. The method of claim 22, further comprising:
extracting the larger crystal from the crucible upon completion of the crystal growth;
coring the extracted larger crystal to produce a substantially cylindrical ingot; and
slicing the cored cylindrical ingot to produce wafers.

24. The method of claim 23, wherein coring the extracted larger crystal comprises:
coring substantially perpendicular to a top surface of the extracted larger crystal to produce the cored cylindrical ingot.

25. The method of claim 24, wherein continually growing the crystal comprises:
continually growing the crystal about an axis selected from the group consisting of a-axis, c-axis, r-axis, and m-axis.

26. The method of claim 25, wherein continually growing the crystal about the a-axis, the c-axis, the r-axis, or the m-axis comprises:
melting a portion of a top surface of the seed crystal to form a convex crystal growing surface and maintaining the convex crystal growing surface.

27. The method of claim 26, wherein the bottom of the crucible is cooled using helium.

28. The method of claim 27, wherein in progressively increasing the cooling rate at the bottom of the crucible, the flow rate of helium is approximately in the range of about 10 to 600 liters per minute (lpm).

29. The method of claim 28, wherein, in heating the charge material along with the seed crystal in the crucible substantially slightly above the melting temperature of the charge material, the temperature is approximately in the range of about 2040° C. to 2100° C.

30. The method of claim 29, wherein the temperature of the melt is substantially lowered at a rate approximately in the range of about 0.02 to 5° C./hr.

31. The method of claim 30, wherein the crucible is substantially lowered at a rate approximately in the range of about 0.1 to 5 mm/hr.

32. A method for growing a crystal in a controlled heat extraction system (CHES), wherein the CHES comprises a housing, a seed cooling component adapted to support a bottom of a crucible and to receive a coolant fluid to cool the supported portion of the crucible, at least one heating element, an insulating element and a gradient control device (GCD), comprising:
heating a charge material along with a seed crystal in the crucible to substantially slightly above a melting temperature of the charge material and maintaining the melt of the charge material for a pre-determined amount of time for homogenization using the at least one heating element;
substantially simultaneously cooling the bottom of the crucible to keep the seed crystal intact by flowing the coolant fluid through the seed cooling component; and
continually growing the crystal by progressively increasing the cooling rate at the bottom of the crucible by flowing the coolant fluid through the seed cooling component, and substantially lowering the crucible with respect to the at least one heating element using the seed cooling component to maintain growth rate of the continually growing crystal to produce a substantially larger crystal.

33. The method of claim 32, wherein continually growing the crystal further comprises:
substantially lowering the temperature of the at least one heating element, and wherein the temperature of the at least one heating element is lowered at a rate approximately in the range of about 0.02 to 5° C./hr.

34. The method of claim 32, wherein continually growing the crystal further comprises:
substantially moving the GCD such that a temperature gradient is varied between the continually growing crystal and the melt.

35. The method of claim 32, wherein continually growing the crystal comprises:
continually growing the crystal about an axis selected from the group consisting of a-axis, c-axis, r-axis and m-axis.

36. The method of claim 35, wherein the continually growing the crystal about the a-axis, the c-axis, r-axis or m-axis comprises:
melting a portion of a top surface of the seed crystal to form a convex crystal growing surface and maintaining the convex crystal growing surface.

37. The method of claim 32, wherein the seed cooling component is made of a refractory metal selected from the group consisting of tungsten (W), molybdenum (Mo), niobium (Nb), lanthanum (La), tantalum (Ta), rhenium (Re) and their alloys.

38. The method of claim 32, wherein the coolant fluid is a fluid selected from the group consisting of helium (He), neon (Ne), and hydrogen (H).

39. The method of claim 38, wherein in progressively increasing the cooling rate at the bottom of the crucible, the flow rate of the cooling fluid is approximately in the range of about 10 to 600 liters per minute (lpm).

40. The method of claim 39, wherein the at least one heating element is capable of heating the charge material in the crucible to a temperature approximately in the range of about 2040° C. to 2100° C.

41. The method of claim 40, wherein the crucible is substantially lowered at a rate approximately in the range of about 0.1 to 5 mm/hr.

42. The method of claim 41, wherein the GCD is substantially moved at a rate approximately in the range of about 0.1 to 5 mm/hr.

43. A system for growing crystals from a molten charge material in a crucible, comprising:
a housing to form a chamber;
a seed cooling component adapted to support a bottom of the crucible and to receive a coolant fluid to cool the supported portion of the crucible;
at least one heating element substantially surrounding the seed cooling component and the crucible to heat the crucible, wherein the at least one heating element is adapted to substantially slowly lower temperature inside the chamber during the crystal growth, and wherein the at least one heating element is designed to cool the chamber at a rate approximately in the range of about 0.02 to 5° C./hr;
an insulating element substantially surrounding the crucible, the seed cooling component and the at least one heating element; and
a gradient control device (GCD) movable relative to the insulating element, the at least one heating element, the seed cooling component and the crucible over a range of positions, and wherein the seed cooling component along with the crucible, the at least one heating element, the insulating element and the GCD are enclosed in the housing.

44. A system for growing crystals from a molten charge material in a crucible, comprising:
a housing to form a chamber;
a seed cooling component adapted to support a bottom of the crucible and to receive a coolant fluid to cool the supported portion of the crucible;
at least one heating element substantially surrounding the seed cooling component and the crucible to heat the crucible, wherein the at least one heating element is adapted to substantially slowly lower temperature inside the chamber during the crystal growth, and wherein the at least one heating element is designed to cool the chamber at a rate approximately in the range of about 0.02 to 5° C./hr, and wherein the seed cooling component along with the crucible is movable relative to the at least one heating element;
an insulating element substantially surrounding the crucible, the seed cooling component and the at least one heating element; and
a gradient control device (GCD) movable relative to the insulating element, the at least one heating element, the seed cooling component and the crucible over a range of positions, and wherein the seed cooling component along with the crucible, the at least one heating element, the insulating element and the GCD are enclosed in the housing.
